(19) United States
(12) Patent Application Publication
(10) Pub. No.: US 2016/0224272 A1
(43) Pub. Date: Aug. 4, 2016

(54) MEMORY DEVICE FOR PERFORMING INFORMATION TRANSMISSION DURING IDLE PERIOD AND METHOD OF OPERATING THE SAME

(71) Applicant: SAMSUNG ELECTRONICS CO., LTD., Suwon-si (KR)

(72) Inventor: Dae-kyoung KIM, Seoul (KR)

(73) Assignee: SAMSUNG ELECTRONICS CO., LTD., Suwon-si (KR)

(21) Appl. No.: 14/957,066

(22) Filed: Dec. 2, 2015

(30) Foreign Application Priority Data
Feb. 2, 2015 (KR) 10-2015-0016187

(51) Int. Cl. G06F 3/06; G06F 1/32; G11C 11/406

(52) U.S. Cl. CPC G06F 3/0647; G06F 3/0604; G06F 3/0634; G06F 3/0673; G11C 11/40615; G06F 1/3296

(57) ABSTRACT

Provided is a memory device performing an information transfer function during an idle period. The memory device includes a command decoder for receiving a command and detecting a transition to an idle period that is a data idle period from the command, and a mode register for storing an information selection signal for selecting internal information of the memory device and outputting the selected internal information during the idle period. The memory device selects at least one from among information about functions, characteristics and modes of the memory device set in the mode register, processing information of a self-refresh operation of the memory device, power-down mode information of the memory device, and internal temperature information of the memory device. The memory device transfers the selected internal information to a memory controller.

### CROSS-REFERENCE TO RELATED APPLICATION

This application claims priority from Korean Patent Application No. 10-2015-0016187, filed on Feb. 2, 2015, in the Korean Intellectual Property Office, the disclosure of which is incorporated herein in its entirety by reference.

### BACKGROUND

1. Field

Apparatuses and methods consistent with exemplary embodiments relate to a semiconductor memory device, and more particularly, to a memory device and a method of transmitting internal information through a data line during an idle period, that is, a data idle period.

2. Description of the Related Art

A system typically includes a processor, a memory device, and a memory controller. The memory controller is provided so that other components of the system, e.g., the processor, may access the memory device. The system may access the memory device in response to a read and/or write memory transaction executed by the processor. An operation of accessing the memory device is controlled by the memory controller controlling the memory device. The memory controller controls the memory device while based on an internal status of the memory device. If the memory device correctly notifies the memory controller of the internal status thereof, the memory controller may access the memory device based on the notified internal status, and accordingly, the performance of the system may be improved.

### SUMMARY

The inventive concept provides a memory device capable of transmitting internal information thereof via a data line during an idle period, that is, a data idle period.

The inventive concept provides a method of operating a memory device that transmits internal information thereof via a data line during an idle period, that is, a data idle period.

The inventive concept provides a system including a memory device for transmitting internal information thereof via a data line during an idle period, that is, a data idle period.

According to an aspect of the inventive concept, there is provided a memory device for providing internal information. The memory device includes a command decoder for receiving a command and detecting a transition to an idle period that is a data idle period from the command, a mode register for storing an information selection signal for selecting internal information of the memory device and outputting the selected internal information during the idle period, and a data pad for transmitting the internal information selected by the information selection signal to an external device during the idle period.

The selected internal information may include at least one of a function, a characteristic, and a mode of the memory device that is set in the mode register.

The command decoder may control the memory device to enter a power-down mode in response to a power-down command, and the selected internal information may include status information indicating that the memory device is in the power-down mode.

The command decoder may control a memory cell row of the memory device to perform a self-refresh operation in response to a self-refresh command, and the selected internal information may include information indicating that the self-refresh operation is performed.

The memory device may further include a refresh address generator for generating a refresh address corresponding to the memory cell row on which the self-refresh operation is performed.

The memory device may further include a temperature detector for sensing an internal temperature of the memory device. The selected internal information may include information about internal temperature of the memory device.

The selected internal information may be provided to a memory controller that transmits the command.

The selected internal information may be serially transmitted to the memory controller via a data line that is connected to the data pad.

The selected internal information may be transmitted to the memory controller in parallel via data lines that are respectively connected to a plurality of data pads.

According to an aspect of the inventive concept, there is provided a method of operating a memory device. The method includes storing an information selection signal in a mode register for selecting internal information of the memory device and outputting the selected internal information, receiving a command and detecting a transition to an idle period, which is a data idle period, from the received command, and transmitting the selected internal information to an external device during the idle period.

The method may further include setting at least one of a function, a characteristic, and a mode of the memory device in the mode register. The selected internal information may include information about the at least one of the function, the characteristic, and the mode of the memory device that is set in the mode register.

The method may further include controlling the memory device to enter a power-down mode in response to a power-down command. The selected internal information may include status information indicating that the memory device is in the power-down mode.

The method may further include performing a self-refresh operation with respect to a memory cell row of the memory device in response to a self-refresh command. The selected internal information may include information indicating that the self-refresh operation is performed.

The method may further include detecting an internal temperature of the memory device. The selected internal information may be internal temperature information of the memory device.

The selected internal information may be serially transmitted via a data line connected to the memory device.

The selected internal information may be transmitted in parallel via a plurality of data lines connected to the memory device.

According to an aspect of the inventive concept, there is provided a system including a memory device for providing internal information, and a memory controller for controlling the memory device. The memory device includes a command decoder for receiving a command, the command decoder including an idle period detector configured to detect a transition to an idle period, which is a data idle period, from the received command, a mode register for selecting internal information of the memory device and outputting the selected internal information during the idle period, and a data pad for transmitting the selected internal information to the memory controller during the idle period.

The selected internal information may include at least one from among information about at least one of a function, a characteristic, and a mode of the memory device that is set in the mode register, information of processing a self-refresh operation of the memory device, power-down mode information of the memory device, and internal temperature information of the memory device.

The system may further include a power management integrated circuit (PMIC) for blocking supply of operating power to the memory controller and the memory device based on the power-down mode information of the memory device.

The selected internal information may be serially transmitted to the memory controller via a data line connected to the data pad or transmitted to the memory controller in parallel via data lines that are respectively connected to a plurality of data pads.

### BRIEF DESCRIPTION OF THE DRAWINGS

The above and/or other aspects will become more apparent by describing certain exemplary embodiments with reference to the accompanying drawings, in which:

FIG. 1 is a diagram of a memory system including a memory device performing information transmission during an idle period, according to an exemplary embodiment of the inventive concept;

FIG. 2 is a diagram of the memory device of FIG. 1, according to an exemplary embodiment of the inventive concept;

FIG. 3 is a diagram of an information decoder of FIG. 2, according to an exemplary embodiment of the inventive concept;

FIG. 4 is a diagram illustrating a method of operating the memory device of FIG. 2, according to an exemplary embodiment of the inventive concept;

FIGS. 5 and 6 are timing diagrams for illustrating operations of the memory system of FIG. 1, according to an exemplary embodiment of the inventive concept;

FIG. 7 is a diagram of a system including a memory device performing information transmission during an idle period according to an exemplary embodiment of the inventive concept;

FIG. 8 is a diagram of a memory device performing information transmission during an idle period, according to an exemplary embodiment of the inventive concept;

FIG. 9 is a block diagram of a mobile system to which a memory device according to an exemplary embodiment is applied; and

FIG. 10 is a block diagram of a computing system including a memory device performing information transmission during an idle period, according to an exemplary embodiment applied thereto.

### DETAILED DESCRIPTION

The attached drawings for illustrating exemplary embodiments are referred to in order to gain a sufficient understanding, the merits thereof, and the objectives accomplished by the implementation.

Hereinafter, the inventive concept will be described more fully with reference to the accompanying drawings, in which exemplary embodiments of the inventive concept are shown. This inventive concept may, however, be embodied in many different forms and should not be construed as limited to the exemplary embodiments set forth herein. Rather, these exemplary embodiments are provided so that this disclosure will be thorough and complete, and will fully convey the scope of the inventive concept to one of ordinary skill in the art. As the inventive concept allows for various changes and numerous embodiments, particular exemplary embodiments will be illustrated in the drawings and described in detail in the written description. However, this is not intended to limit the inventive concept to particular modes of practice, and it is to be appreciated that all changes, equivalents, and substitutes that do not depart from the spirit and technical scope are encompassed in the inventive concept. Sizes of components in the drawings may be exaggerated for convenience of explanation.

Meanwhile, the terminology used herein is for the purpose of describing particular exemplary embodiments only and is not intended to be limiting of exemplary embodiments. As used herein, the singular forms “a”, “an”, and “the” are intended to include the plural forms as well, unless the context clearly indicates otherwise. It will be further understood that the terms “comprises” and/or “comprising” used herein specify the presence of stated features, integers, steps, operations, members, components, and/or groups thereof, but do not preclude the presence or addition of one or more other features, integers, steps, operations, members, components, and/or groups thereof.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, the term “and/or” includes any and all combinations of one or more of the associated listed items. Expressions such as “at least one of,” when preceding a list of elements, modify the entire list of elements and do not modify the individual elements of the list.

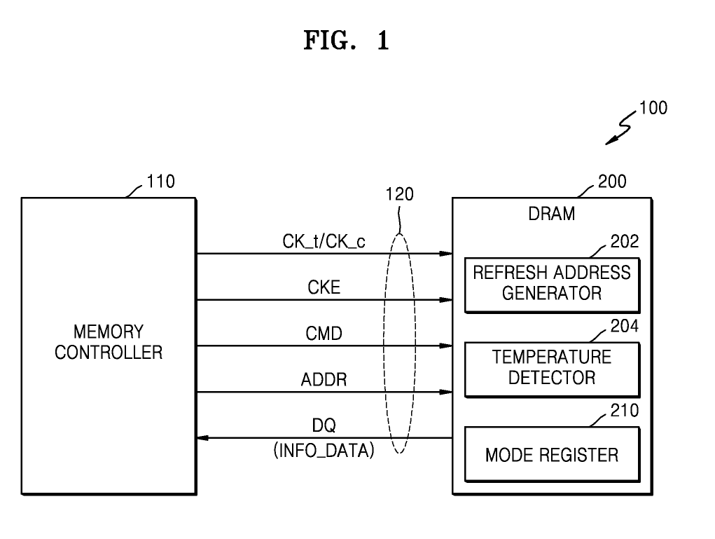

FIG. 1 is a diagram of a memory system 100 including a memory device 200 performing an information transmission function during an idle period, according to an exemplary embodiment of the inventive concept.

Referring to FIG. 1, the memory system 100 may include a memory controller 110 and the memory device 200. The memory system 100 may allocate program codes, that is, a collection of commands and data, to the memory device 200, for executing application programs of a processor. The memory controller 110 may be built in the processor, or may be realized as a separate chip from the processor, and then may be connected to the processor. The memory controller 110 may support read and/or write memory transaction in order to access the memory device 200.

According to the exemplary embodiment, the memory controller 110 may execute a memory transaction of a chipset configuring the system 100, other than the processor. For example, if the system 100 includes a computing device, the chipset may include one or more integrated circuit (IC) packages or chips, which connect components, such as basic input/output system (BIOS) firmware, keyboards, a mouse, storage devices, network interfaces, and power management integrated circuits (PMICs), to the processor.

The memory controller 110 may be connected to the memory device 200 via a bus 120. Clock signals CK_t/CK_c, clock enable signals CKE, commands CMD, an address ADDR, and data DQ output from the memory controller 110 may be transferred to the memory device 200 via the bus 120. The data DQ output from the memory device 200 in response to the commands CMD and addresses ADDR of the memory controller 110 may be transferred to the memory controller 110 via the bus 120. According to the exemplary embodiment, a command bus and an address bus in the bus 120 are each configured as one line so as to time-serially transfer the commands CMD and the addresses ADDR.

The memory device 200 may include various memory devices for providing addressable storage locations where data may be read and/or written by the memory controller 110. The memory device 200 may include, for example, dynamic random access memory (DRAM) devices, synchronous DRAM (SDRAM) devices, double data rate (DDR) SDRAM devices, or other memory devices.

The memory controller 110 may access the memory device 200 in response to read and/or write memory transactions of the processor. An operation of accessing the memory device 200 may be affected by memory read latency and memory write latency.

In general, the memory read latency denotes a time period between a time when the memory controller 110 requests the memory device 200 to search for data and retrieve the data, and a time when the memory device 200 provides the requested data to the memory controller 110. The memory write latency denotes a time period between a time when the memory controller 110 requests the memory device 200 to write the data, and a time when the memory device 200 notifies the memory controller 110 that the data writing operation has finished. In view of the memory read latency and the memory write latency, the memory controller 110 and the memory device 200 may send and/or receive data to and/or from each other via a DQ bus of the bus 120.

The memory controller 110 may control refresh operations of the memory device 200, to retain the data stored in DRAM memory cells. Data is written to the DRAM memory cells based on electric charges stored in a cell capacitor. In accordance with scaling of a DRAM, a capacitance value of the cell capacitor decreases. Also, since a leakage current occurs in the cell capacitor, the electric charges stored in the cell capacitor are removed as time elapses even when the read and write operations are not being performed. Accordingly, a bit error rate increases, and the reliability of data stored in the memory cells may be degraded. The DRAM performs a refresh operation in order to retain the data stored in the DRAM memory cells.

The memory controller 110 may generate and transmit a refresh command to the memory device 200 in order to control the refresh operation of the memory device 200. The refresh command may be classified as an auto-refresh command for controlling an automatic refresh operation and a self-refresh command for controlling a self-refresh operation. The memory device 200 may include a refresh address generator 202 that generates a refresh row address so that memory cells connected a memory cell row may be refreshed in response to the refresh command. The refresh address generator 202 may generate the refresh row address corresponding to the memory cell row by performing a counting operation in response to the self-refresh command.

When the memory controller 110 accesses the memory device 200, the memory controller 110 may not access the memory device 200 during the self-refresh operation of the memory device 200. Accordingly, the memory controller 110 needs to monitor the refresh status of the memory device 200. The memory device 200 may perform the refresh operation in response to the self-refresh command, and may transmit the refresh status to the memory controller 110 via the DQ bus 120 during the refresh operation.

The memory capacity of the memory device 200 is increased to provide a fast and high capacitive memory system 100. As the memory capacity of the memory device 200 increases, a refresh current consumption increases, thereby increasing refresh power consumption. The memory device 200 has a temperature characteristic according to operations thereof. That is, the operating speed of the memory device 200 lowers when a temperature rises, and current consumption of the memory device 200 increases when the temperature lowers. Since the leakage current in the DRAM cells of the memory device 200 increases when the temperature rises, data retention characteristics due to the electric charges may be degraded and the data retention time may be shortened.

One of methods for reducing the power consumption of the memory device 200 is to change a refresh period according to temperature. In a low temperature section in which current consumption increases, the refresh period relatively increases in order to reduce a refresh clock frequency, and the power consumption may be reduced. Accordingly, the memory device 200 may need a temperature detector 204 in order to determine an internal temperature thereof. The internal temperature information of the memory device 200 may be used by the memory controller 110 that controls the refresh operation to change the refresh period. The memory device 200 may transfer the internal temperature information detected by the temperature detector 204 to the memory controller 110 via the DQ bus 120.

In order to reduce the power consumption of the memory device 200, the memory controller 110 may control a power-down mode of the memory device 200. The memory controller 110 may generate a power-down command and transmit the power-down command to the memory device 200. The memory device 200 enters the power-down mode in response to the power-down command, and notifies the memory controller 110 that the internal operation mode is the power-down mode via the DQ bus 120.

The memory controller 110 may generate a mode register set (MRS) command in order to set various functions, characteristics, and modes of the memory device 200, and may transmit predetermined bit values to the memory device 200 via the address bus of the bus 120. The memory device 200 may set a mode register 210 by using the predetermined bit values provided via the address bus 120 in response to the MRS command.

The mode register 210 may set a burst length, a read burst type, column address strobe (CAS) latency, a test mode, delay locked loop (DLL) reset, write recovery and read command-to-precharge command characteristics, DLL usage during precharge power-down, and DLL enable/disable of the memory device 200.

In the memory device 200, the burst length may determine a maximum number of column locations that are accessible with respect to a read or write command corresponding thereto. The burst length may be adjusted as BL8 or BC4. BL8 denotes a burst length of 8, and BC4 denotes a burst length of 4 that is obtained by chopping 4 from the burst length 8.

In the memory device 200, the read burst type defines an order of data provided by the memory device 200 via a data terminal, and may be set as a sequential burst mode in which data is provided sequentially and as an interleave burst mode in which data is provided in an interleaved manner.

In the memory device 200, the CAS latency is expressed by the number of clock cycles. The CAS latency denotes a clock cycle delay between the read command of the memory device 200 and a first bit of effective output data. The CAS latency may be set as CAS latency 9, 10, 11, 12, 13, 14, 15, 16, 18, 20, 22, or 24.

The memory device 200 may set a test mode, provide DLL reset characteristics and provide the write recovery and the read command-to-precharge characteristics for performing automatic precharge. The write recovery time is a time period between a time when a final bit is written in the automatic precharge operation and a time when the memory device 200 is able to perform the precharge operation thereof. In order to automatically start the precharge operation immediately when a previous operation has finished, that is, in order not to generate undesired delay, the memory controller 110 may set the write recovery time and the read-to-precharge time to a predetermined time (ns) period.

The memory device 200 may select DLL usage during precharge power-down mode. For example, the DLL is turned off (or frozen) after entering the precharge power-down mode to save power, and the DLL needs to satisfy a predetermined timing before a next effective command is received when the DLL exits the power-down mode.

The memory device 200 may select DLL enable or DLL disable. The DLL needs to be enabled to perform a normal operation. The DLL enabling is needed during a power-up initialization and when returning to a normal operation after the DLL disabling.

The mode register 210 may set various functions, characteristics, and modes of the memory device 200, and may set which information is to be selected from among the internal information of the memory device 200 and transferred to the memory controller 110 when the memory device 200 is in an idle period, that is, the data idle period.

The mode register 210 may be set so that at least one selected from information about the functions, characteristics and modes of the memory device 200 set in the mode register 210, process information of the self-refresh operation of the memory device 200, the power-down mode information of the memory device 200, and the temperature information of the memory device 200 may be transferred to the memory controller 110.

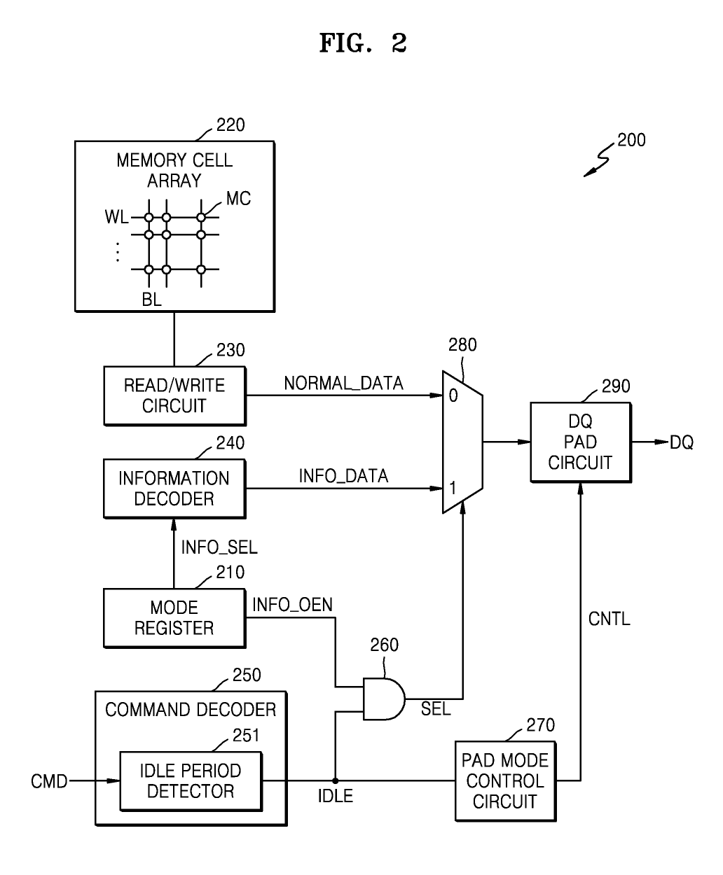

FIG. 2 is a diagram of the memory device 200 of FIG. 1, according to an exemplary embodiment of the inventive concept.

Referring to FIG. 2, the memory device 200 may include the mode register 210, a memory cell array 220, a read/write circuit 230, an information decoder 240, an idle period detector 251, a logic circuit 260, a pad mode control circuit 270, a selection circuit 280, and a DQ pad circuit 290.

The mode register 210 may set various functions, characteristics, and modes of the memory device 200. Also, when the memory device 200 is in the idle period, in which data is not transferred, the mode register 210 may store an information selection signal INFO_SEL indicating which information from among the internal information of the memory device 200 is to be selected and an information output signal INFO_OEN indicating whether the selected information is to be transferred to the memory controller 110 (see FIG. 1).

The information selection signal INFO_SEL is provided as at least one piece of bit information together with the MRS command from the memory controller 110 (see FIG. 1) to the information decoder 240. The information output signal INFO_OEN may be output as, for example, a flag signal of a logic high level, to the logic circuit 260.

The memory cell array 220 may include a plurality of memory cells MCs arranged in columns and rows. Word lines WLs arranged in a row direction and bit lines BLs arranged in a column direction cross each other to form a matrix structure. The plurality of memory cells MCs are respectively arranged on cross points in the matrix. Each of the plurality of memory cells MCs may include one access transistor and one storage capacitor.

The read/write circuit 230 may include read circuits for sensing and amplifying data read from the memory cell array 220, and write circuits for driving data to be written in the memory cell array 220. Data output from the read/write circuit unit 230 according to a read operation of the memory device 200 is referred to as normal data NORMAL_DATA.

The information decoder 240 may select internal information of the memory device 200, which is to be output in the idle period of the memory device 200, in response to the information selection signal INFO_SEL. The internal information of the memory device 200 may include information about various functions, characteristics, and modes of the memory device 200 which is stored in the mode register 210, information about refresh operation performed by the memory cell array 220 through the refresh address generator 202 (see FIG. 1), operation state information indicating whether the memory device 200 is in the power-down mode or the normal operation mode, and internal temperature information detected by the temperature detector 204 (see FIG. 1) of the memory device 200. The information decoder 240 may select at least one from the mode register information, the refresh information, the operation state information, and the temperature information in response to the information selection signal INFO_SEL, and may output the selected information as information data INFO_DATA.

The idle period detector 251 may detect transition in the operation status of the memory device 200 in response to a command CMD. The idle period detector 251 may be included in a command decoder 250. The idle period detector 251 may detect that the memory device 200 has transited to the idle period, that is, the data idle period, in response to the self-refresh command or the power-down command, and may generate an idle signal IDLE. For example, if the memory device 200 has transited to the idle period, the idle period detector 251 may generate the idle signal IDLE of a logic high level. The idle signal IDLE may be provided to the logic circuit 260 and the pad mode control circuit 270.

The logic circuit 260 receives an information output signal INFO_OEN and the idle signal IDLE, and generates an output selection signal SEL by performing an AND operation on the information output signal INFO_OEN and the idle signal IDLE. For example, if both the information output signal INFO_OEN and the idle signal IDLE are in a logic high level, the logic circuit 260 may generate the output selection signal SEL of the logic high level. The output selection signal SEL may be provided to the selection circuit 280.

The pad mode control circuit 270 may generate a pad mode control signal CNTL according to the idle signal IDLE. For example, the pad mode control circuit 270 may output the pad mode control signal CNTL of a logic high level according to the idle signal IDLE of the logic high level. The pad mode control signal CNTL of the logic high level is provided to the DQ pad circuit 290.

The selection circuit 280 may select one of the normal data NORMAL_DATA output from the read/write circuit unit 230 and the information data INFO_DATA output from the information decoder 240 in response to the output selection signal SEL, and then, may transfer the selected data to the DQ pad circuit 290. For example, the selection circuit 280 may select the normal data NORMAL_DATA in response to the output selection signal SEL of a logic low level, and may select the information data INFO_DATA in response to the output selection signal SEL of a logic high level. The normal data NORMAL_DATA or the information data INFO_DATA selected by the selection circuit 280 may be transferred to the DQ pad circuit 290.

The DQ pad circuit 290 may output the normal data NORMAL_DATA or the information data INFO_DATA selected by the selection circuit 280 to a DQ pad DQ in response to the pad mode control signal CNTL. For example, if the pad mode control signal CNTL is in a logic high level, the data selected by the selection circuit 280 is the information data INFO_DATA, and thus, the DQ pad circuit 290 may output the information data INFO_DATA to the DQ pad DQ. On the other hand, if the pad mode control signal CNTL is a logic low level signal, the data selected by the selection circuit 280 is the normal data NORMAL_DATA, and thus, the DQ pad circuit 290 may output the normal data NORMAL_DATA to the DQ pad DQ. The normal data NORMAL_DATA or the information data INFO_DATA output to the DQ pad DQ may be transferred to the memory controller 110 (see FIG. 1) via the DQ bus 120 (see FIG. 1).

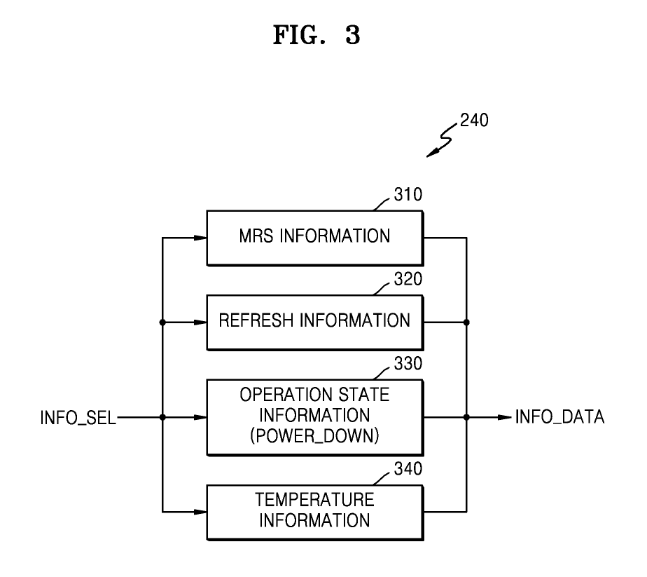

FIG. 3 is a diagram of the information decoder 240 of FIG. 2, according to an exemplary embodiment of the inventive concept.

Referring to FIG. 3, the information decoder 240 may select one of mode register information (or mode register set (MRS) information) 310, refresh information 320, operation state information 330, and temperature information 340 in response to the information selection signal INFO_SEL, and output the selected information as information data INFO_DATA. The mode register information 310 may be information about various functions, characteristics, and modes of the memory device 200 which is stored in the mode register 210 (see FIG. 1). The refresh information 320 may be information about the refresh operation performed at the memory cell array 220 (see FIG. 2) through the refresh address generator 202 (see FIG. 1). The operation state information 330 may be information indicating whether the memory device 200 is in the power-down mode or in the normal operation mode. The temperature information 340 may be internal temperature information detected by the temperature detector 204 (see FIG. 1) of the memory device 200.

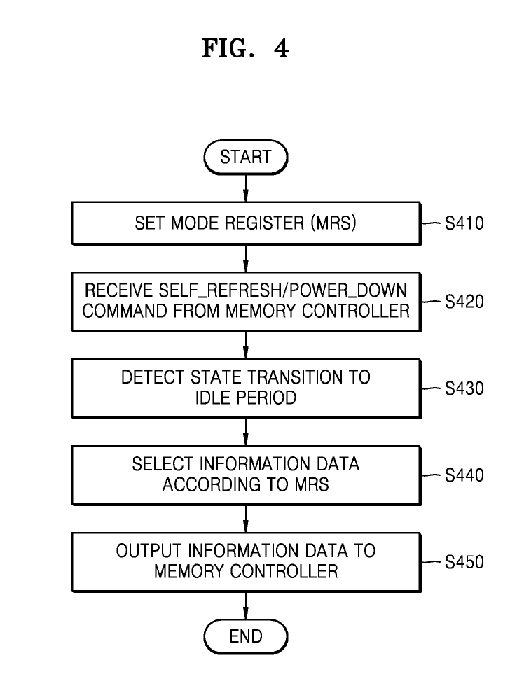

FIG. 4 is a diagram illustrating a method of operating the memory device 200 of FIG. 2, according to an exemplary embodiment of the inventive concept.

Referring to FIG. 4 and FIG. 2, in order to set various functions, characteristics, and modes of the memory device 200, the mode register 210 may be set (or set MRS information) (S410). In addition, the mode register 210 may store the information selection signal INFO_SEL indicating which information from among the internal information of the memory device 200 is to be selected and the information output signal INFO_OEN indicating whether the selected information is to be transferred to the memory controller 110 (see FIG. 1) when the memory device 200 is in the idle period, that is, the data idle period.

The memory device 200 may receive a self-refresh command or a power-down command from the memory controller 110 (S420). The memory device 200 may detect that the state of the memory device 200 has transited to the idle period, and generate an idle signal IDLE in response to the self-refresh command and the power-down command (S430).

The memory device 200 may select one of the mode register information, the refresh information, the operation state information, and the temperature information as the information data INFO_DATA in response to the information selection signal INFO_SEL stored in the mode register 210 in the idle period (S440).

The memory device 200 may transfer the information data INFO_DATA to the memory controller 110 (see FIG. 1) via the DQ bus 120 (see FIG. 1) based on the information output signal INFO_OEN and the idle signal IDLE (S450).

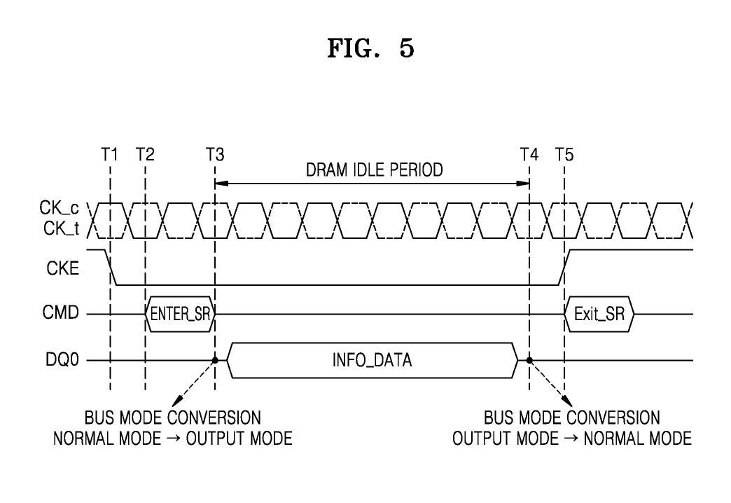

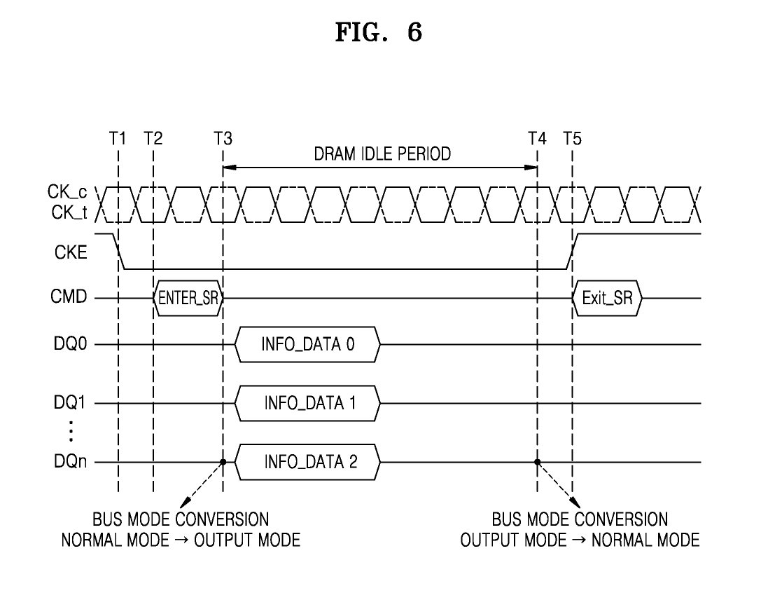

FIGS. 5 and 6 are timing diagrams illustrating operations of the memory system 100 of FIG. 1. FIG. 5 shows an example in which the internal information of the memory device 200 is serially transferred by using a data line DQ0, and FIG. 6 shows an example in which the internal information of the memory device 200 is transferred in parallel by using a plurality of data lines DQ0 to DQn.

Referring to FIG. 5, the memory controller 110 may transmit a clock enable signal CKE and a command CMD to the memory device 200 at rising edges and/or falling edges of differential clock signals CK_t and CK_c. At a time point T1, the clock enable signal CKE is inactivated to a logic low level, and at a time point T2, a self refresh entering command ENTER_SR may be issued.

The memory device 200 enters a self-refresh mode in response to the self-refresh command SR, and may change a mode of the DQ bus 120 at a time point T3. Since the memory device 200 has transited to the idle period, that is, the data idle period, during the self-refresh mode, the DQ bus 120 may be changed from a normal mode for performing the read/write operations to an output mode for transmitting the internal information of the memory device 200.

The memory device 200 may have the idle period from the time point T3 to a time point T4 when the DQ bus 120 is changed to the normal mode again. During the idle period of the memory device 200, one of the mode register information, the refresh information, the operation state information, and the temperature information of the memory device 200 may be selected and output as the information data INFO_DATA. The selected information data INFO_DATA may be transferred to the memory controller 110 in series through one DQ line DQ0 of the DQ bus 120.

After that, the clock enable signal CKE is activated to a logic high level at a time point T5, and a self refresh exit command EXIT_SR may be issued.

Referring to FIG. 6, during the idle period of the memory device 200, two or more pieces of information may be selected from among the mode register information, the refresh information, the operation state information, and the temperature information of the memory device 200. Selected pieces of information data INFO_DATA0, INFO_DATA1, and INFO_DATA2 may be transferred to the memory controller 110 in parallel through the DQ lines DQ0 to DQn of the DQ bus 120.

As described above, since the memory device 200 provides the internal information thereof to the memory controller 110, the memory controller 110 may access the memory device 200 based on the status of the memory device 200.

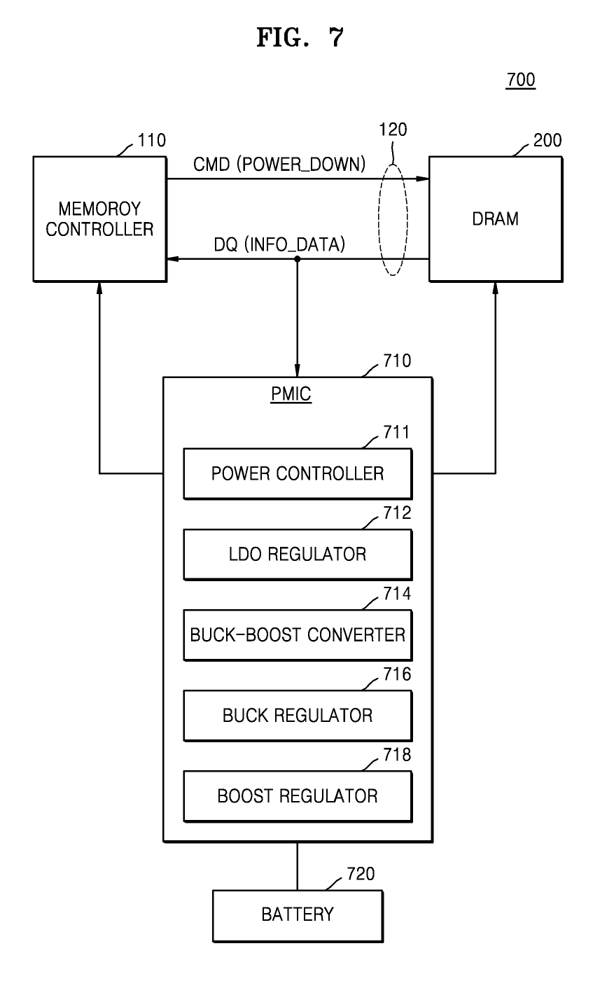

FIG. 7 is a diagram of a system 700 including the memory device 200 for performing information transferring function during an idle period according to an exemplary embodiment.

Referring to FIG. 7, the system 700 may include the memory controller 110, the memory device 200, and a power management integrated circuit (PMIC) 710. The system 700 may be an electronic device such as a portable terminal. The PMIC 710 may be provided to supply electric power stably to electronic devices as the electronic devices become smaller and miniaturized.

The memory device 200, as described above with reference to FIG. 1, may select one of the mode register information, the refresh information, the operation state information, and the temperature information of the memory device 200 during the idle period of the memory device 200, and transfer the selected information data to the memory controller 110 via the DQ bus 120. The memory controller 110 may generate the power-down command and transmit the power-down command to the memory device 200. The memory device 200 enters the power-down mode in response to the power-down command POWER_DOWM and notifies the memory controller 110 of the power-down status thereof via the DQ bus 120.

The PMIC 710 may generate operating power of the memory controller 110 and the memory device 200 by converting a charging voltage of a battery 720, and may supply the operating power to the memory controller 110 and the memory device 200. The PMIC 710 may be connected to the DQ bus 120 that is connected between the memory controller 110 and the memory device 200. The PMIC 710 may block the supply of the operating power to the memory controller 110 and the memory device 200, when the operating status information indicating that the memory device 200 is in the power-down mode is transferred to the memory controller 110 via the DQ bus 120 during the idle period of the memory device 200.

The PMIC 710 may include a power controller 711, a low-dropout (LDO) regulator 712, a buck-boost converter 714, a buck regulator 716, and a boost regulator 718. The power controller 711 may selectively block the supply of the operating power to the memory controller 110 and the memory device 200, when the information data INFO_DATA indicating that the memory device 200 is in the power-down mode is transferred via the DQ bus 120.

The LDO regulator 712 is a linear voltage adjuster operating with a very small differential voltage, and may regulate the output voltage of the buck-boost converter 714 as operating power of the memory controller 110 and the memory device 200. The buck-boost converter 714 senses a voltage of the battery 720. If the voltage of the battery 720 is higher than the set output voltage of the buck-boost converter 714, the buck-boost converter 714 operates in a buck-mode, and if the voltage of the battery 720 is lower than the output voltage of the buck-boost converter 714, the buck-boost converter 714 operates in a boost-mode to generate a constant output voltage.

The buck regulator 716 is a buck DC/DC converter that may generate a set voltage by bucking the input voltage. The buck regulator 716 may have a structure, in which input power is connected to a circuit when a switch is turned on and is not connected to the circuit when the switch is turned off, by using a switching device that turns on/off at a predetermined period. As such, a pulse-type voltage that is periodically connected and blocked is averaged by using an LC filter to output the DC voltage. The boost regulator 718 is a boost DC/DC converter. When a switch is turned on, an input voltage of the boost regulator 718, that is, the output voltage of the battery 720, is connected to opposite terminals of an inductor to charge electric current, and when the switch is turned off, the charged current may be transferred to a load side.

As described above, the operating power supply to the memory controller 110 and the memory device 200 is blocked based on the power-down mode information of the memory device 200 by using the PMIC 710, and accordingly, the power consumption of the system 700 may be reduced.

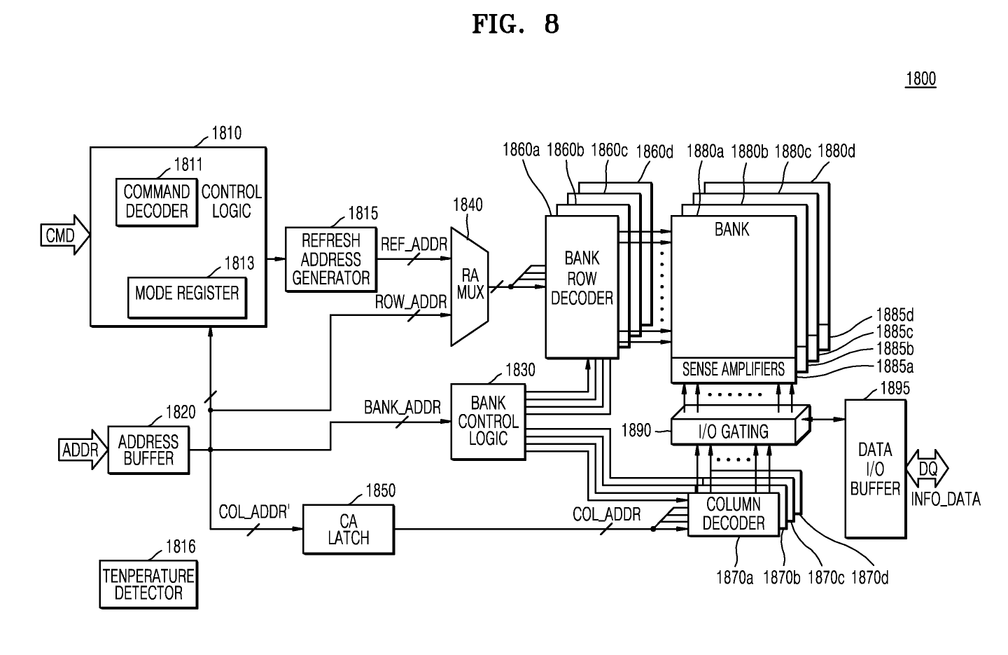

FIG. 8 is a diagram of a memory device 1800 for performing information transfer during an idle period according to an exemplary embodiment.

Referring to FIG. 8, the memory device 1800 may include a control logic 1810, a refresh address generator 1815, a temperature detector 1816, an address buffer 1820, a bank control logic 1830, a row address multiplexer 1840, a column address latch 1850, a row decoder, a memory cell array, a sense amplifier, an input/output (I/O) gating circuit 1890, and a data I/O buffer 1895.

The memory cell array may include first to fourth bank arrays 1880a, 1880b, 1880c, and 1880d. Each of the first to fourth bank arrays 1880a, 1880b, 1880c, and 1880d includes a plurality of memory cell rows (or pages), and may respectively include sense amplifiers 1885a, 1885b, 1885c, and 1885d for sensing and amplifying memory cells connected to each of the memory cell rows.

The row decoder may include first to fourth bank row decoders 1860a, 1860b, 1860c, and 1860d respectively connected to the first to fourth bank arrays 1880a, 1880b, 1880c, and 1880d. The column decoder may include first to fourth bank column decoders 1870a, 1870b, 1870c, and 1870d respectively connected to the first to fourth bank arrays 1880a, 1880b, 1880c, and 1880d.

The first to fourth bank arrays 1880a, 1880b, 1880c, and 1880d, the first to fourth bank row decoders 1860a, 1860b, 1860c, and 1860d, and the first to fourth bank column decoders 1870a, 1870b, 1870c, and 1870d may respectively form first to fourth memory banks. FIG. 8 shows the memory device 1800 including four memory banks, but the number of memory banks included in the memory device 1800 is not limited thereto.

Also, according to some embodiments, the memory device 1800 may be a DRAM, such as double data rate synchronous DRAM (DDR SDRAM), low power double data rate (LPDDR) SDRAM, graphic double data rate (GDDR) SDRAM, or rambus DRAM (RDRAM).

The control logic 1810 may control operations of the memory device 1800. For example, the control logic 1810 may generate control signals through which the memory device 1800 performs a write operation or a read operation. The control logic 1810 may include a command decoder 1811 that decodes a command CMD received from a memory controller, and a mode register 1813 that sets an operation mode of the memory device 1800.

The command decoder 1811 may generate control signals corresponding to the command CMD by decoding a write enable signal /WE, a row address strobe signal /RAS, a column address strobe signal /CAS, or a chip select signal /CS. The command CMD may include an active command, a read command, a write command, a precharge command, a refresh command, or a power-down command. The command decoder 1811 enters the power-down mode in response to the power-down command, and may notify the memory controller that the internal operating status is the power-down mode via the DQ pad.

The mode register 1813 provides a plurality of operating options of the memory device 1800, and may program various functions, characteristics, and modes of the memory device 1800. The mode register 1813 may store an information selection signal and an information output signal for selecting at least one from among the mode register information, the refresh information, the operation state information and the temperature information of the memory device 1800 when the memory device 1800 is in the idle period, that is, the data idle period, and outputting the selected information as the information data INFO_DATA via a DQ pin.

The control logic 1810 may further receive differential clock signals CLK_t/CLK_c and a clock enable signal CKE for driving the memory device 1800 in a synchronization manner. The data of the memory device 1800 may operate at a double data rate. The clock enable signal CKE may be captured at the rising edge of the clock CLK_t.

The control logic 1810 may control the refresh address generator 1815 to perform an auto-refresh operation in response to the refresh command, or may control the refresh address generator 1815 to perform a self-refresh operation in response to the self refresh entering command.

The refresh address generator 1815 may generate a refresh address REF_ADDR corresponding to the memory cell row on which the refresh operation is to be performed. The refresh address generator 1815 may generate the refresh address REF_ADDR at a refresh period defined by the standard of the non-volatile memory device or a refresh period changed according to the internal temperature detected by the temperature detector 1816. Information about the refresh process performed by the refresh address generator 1815 may be transferred to the memory controller via the DQ pad.

The temperature detector 1816 detects the internal temperature of the memory device 1800 and outputs the detected temperature. The internal temperature information detected by the temperature detector 1816 may be transferred to the memory controller via the DQ pad when the memory device 1800 is in the idle period, that is, the data idle period.

The address buffer 1820 may receive an address ADDR including a bank address BANK_ADDR, a row address ROW_ADDR, and a column address COL_ADDR from the memory controller. Also, the address buffer 1820 may provide the bank address BANK_ADDR to the bank control logic 1830, provide the row address ROW_ADDR to the row address multiplexer 1840, and provide the column address COL_ADDR to the column address latch 1850.

The bank control logic 1830 may generate bank control signals in response to the bank address BANK_ADDR. In response to the bank control signals, a bank row decoder corresponding to the bank address BANK_ADDR from among the first to fourth bank row decoders 1860a to 1860d may be activated, and a bank column decoder corresponding to the bank address BANK_ADDR from among the first to fourth bank column decoders 1870a to 1870d may be activated.

The bank control logic 1830 may generate bank group control signals in response to the bank address BANK_ADDR for determining a bank group. In response to the bank group control signals, row decoders of a bank group corresponding to the bank address BANK_ADDR from among the first to fourth bank row decoders 1860a to 1860d may be activated, and column decoders of a bank group corresponding to the bank address BANK_ADDR from among the first to fourth bank column decoders 1870a to 1870d may be activated.

The row address multiplexer 1840 may receive the row address ROW_ADDR from the address buffer 1820 and the refresh address REF_ADDR from the refresh address generator 1815. The row address multiplexer 1840 may selectively output the row address ROW_ADDR or the refresh address REF_ADDR. The row address ROW_ADDR output from the row address multiplexer 1840 may be applied to each of the first to fourth bank row decoders 1860a to 1860d.

The bank row decoder activated by the bank control logic 1830 from among the first to fourth bank row decoders 1860a to 1860d may decode the row address ROW_ADDR output by the row address multiplexer 1840 and activate a word line corresponding to the row address ROW_ADDR. For example, the activated bank row decoder may apply a word line driving voltage to the word line corresponding to the row address ROW_ADDR.

The column address latch 1850 may receive the column address COL_ADDR from the address buffer 1820 and temporarily store the column address COL_ADDR. The column address latch 1850 may gradually increase the column address COL_ADDR in a burst mode. The column address latch 1850 may apply the column address COL_ADDR that is temporarily stored or gradually increased to each of the first to fourth bank column decoders 1870a to 1870d.

The bank column decoder activated by the bank control logic 1830 from among the first to fourth bank column decoders 1870a to 1870d may activate a sense amplifier corresponding to the bank address BANK_ADDR and the column address COL_ADDR through the I/O gating circuit 1890.

The I/O gating circuit 1890 may include, together with circuits for gating I/O data, an input data mask logic, read data latches for storing data output from the first to fourth bank arrays 1880a to 1880d, and write drivers for writing data to the first to fourth bank arrays 1880a to 1880d.

The data to be written to the memory cell array of the one of the first to fourth bank arrays 1880a to 1880d may be provided to the data I/O buffer 1895 from the memory controller via the memory buffer. The data provided to the data I/O buffer 1895 may be written to the one bank array through a write driver.

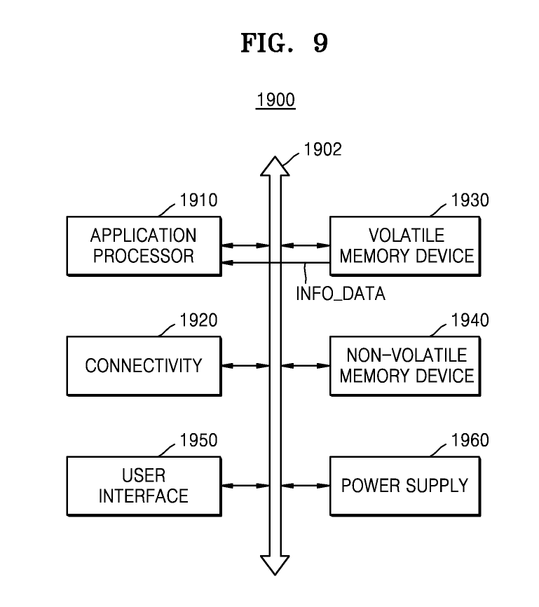

FIG. 9 is a block diagram of a mobile system 1900 to which a memory device performing the information transfer function in the idle period is applied, according to an exemplary embodiment.

Referring to FIG. 9, the mobile system 1900 may include an application processor 1910, a connectivity unit 1920, a first memory device 1930, a second memory device 1940, a user interface 1950, and a power supply source 1960, which are connected to each other via a bus 1902. The first memory device 1930 may be a volatile memory device, and the second memory device 1940 may be a non-volatile memory device. According to some embodiments, the mobile system 1900 may be an arbitrary mobile system, such as a mobile phone, a smart phone, a personal digital assistant (PDA), a portable multimedia player (PMP), a digital camera, a music player, a portable game console, or a navigation system.

The application processor 1910 may execute applications that provide an Internet browser, a game, and/or a video. According to some embodiments, the application processor 1910 may include a single core or a multi-core processor. For example, the application processor 1910 may include a dual-core, a quad-core, or a hexa-core processor. Also, according to some embodiments, the application processor 1910 may further include an internal or external cache memory.

The connectivity unit 1920 may perform wireless communication or wired communication with an external apparatus. For example, the connectivity unit 1920 may perform Ethernet communication, near field communication (NFC), radio frequency identification (RFID) communication, mobile telecommunication, memory card communication, or universal serial bus (USB) communication. For example, the connectivity unit 1920 may include a baseband chipset and may support communication, such as global system for mobile communication (GSM), gross rating points (GRPS), wideband code division multiple access (WCDMA), or high speed packet access (HSxPA).

The first memory device 1930 that is a volatile memory device may store data processed by the application processor 1910 or may operate as a working memory. The first memory device 1930 may set the mode register so that at least one information from among information about the functions, characteristics, and modes of the memory device, information about the self-refresh operation, power-down mode information, and internal temperature information in the mode register may be selected and output. The first memory device 1930 may transmit the selected internal information as the information data INFO_DATA to the application processor 1910 in response to a received command during the idle period, that is, the data idle period.

The second memory device 1940 that is a nonvolatile memory device may store a boot image for booting the mobile system 1900. For example, the second memory device 1940 may be electrically erasable programmable read-only memory (EEPROM), a flash memory, PRAM, resistance random access memory (RRAM), nano-floating gate memory (NFGM), polymer random access memory (PoRAM), magnetic random access memory (MRAM), ferroelectric random access memory (FRAM), or a memory similar thereto.

The user interface 1950 may include at least one input device, such as a keypad or a touch screen, and/or at least one output device, such as a speaker or a display device. The power supply source 1960 may supply an operation voltage. Also, according to some embodiments, the mobile system 1900 may further include a camera image processor (CIP), and may further include a storage device, such as a memory card, a solid state drive (SSD), a hard disk drive (HDD), or a compact disk-read only memory (CD-ROM).

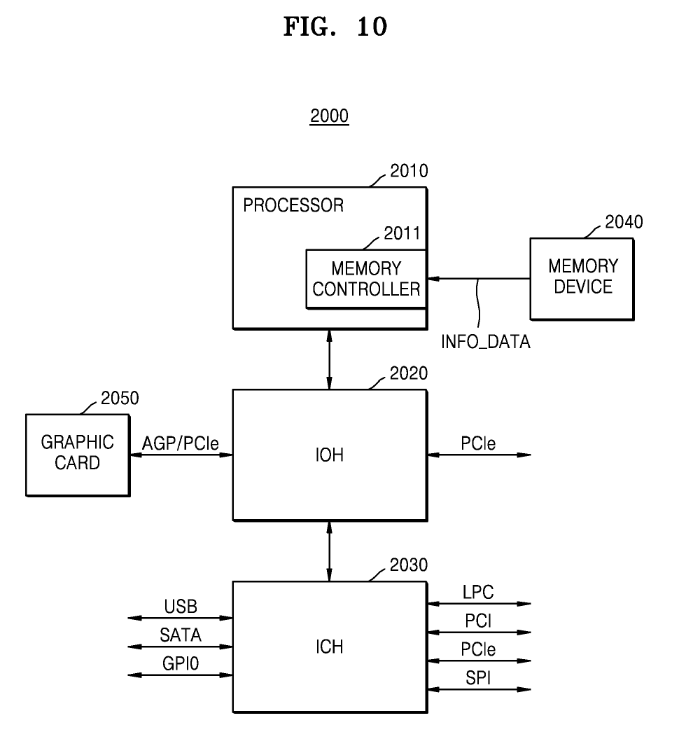

FIG. 10 is a block diagram of a computing system 2000 to which a memory device performing an information transfer function during an idle period is applied, according to an exemplary embodiment.

Referring to FIG. 10, the computing system 2000 includes a processor 2010, an I/O hub (IOH) 2020, an I/O controller hub (ICH) 2030, a memory device 2040, and a graphics card 2050. According to some embodiments, the computing system 2000 may be an arbitrary computing system, such as a personal computer (PC), a server computer, a workstation, a laptop, a mobile phone, a smart phone, a PDA, a PMP, a digital camera, a digital television (DTV), a set-top box, a music player, a portable game console, or a navigation system.

The processor 2010 may execute various computing functions, such as certain calculations or tasks. For example, the processor 2010 may be a microprocessor or a central processing unit (CPU). According to some embodiments, the processor 2010 may include a single core or a multi-core processor. For example, the processor 2010 may include a dual-core, a quad-core, or a hexa-core processor. Also, in FIG. 10, the computing system 2000 includes one processor 2010; however, according to embodiments, the computing system 2000 may include a plurality of processors 2010. In addition, according to some embodiments, the processor 2010 may further include an internal or external cache memory.

The processor 2010 may include a memory controller 2011 that controls operations of the memory device 2040. The memory controller 2011 included in the processor 2010 may be referred to as an integrated memory controller (IMC). A memory interface between the memory controller 2011 and the memory device 2040 may be one channel including a plurality of signal lines or a plurality of channels. Also, at least one memory device 2040 may be connected to each channel. According to some embodiments, the memory controller 2011 may be disposed inside the IOH 2020. The IOH 2020, including the memory controller 2011, may be referred to as a memory controller hub (MCH).

The memory device 2040 may set the mode register so that at least one piece of information from among information about the functions, characteristics, and modes of the memory device, information about the self-refresh operation, power-down mode information, and internal temperature information in the mode register may be selected and output. The memory device 2040 may transmit the selected internal information as the information data INFO_DATA to the memory controller 2011 in response to a received command during the idle period, that is, the data idle period.

The IOH 2020 may manage data transmission between apparatuses, such as the graphics card 2050, and the processor 2010. The IOH 2020 may be connected to the processor 2010 via any type of interface. For example, the IOH 2020 and the processor 2010 may be connected to each other via an interface according to any of various standards, such as a front side bus (FSB), a system bus, HyperTransport, lighting data transport (LDT), quick path interconnect (QPI), a common system interface, and peripheral component interface-express (PCIe). In FIG. 10, the computing system 2000 includes one IOH 2020. However, according to embodiments, the computing system 2000 may include a plurality of IOHs 1120.

The IOH 2020 may provide various interfaces with apparatuses. For example, the IOH 2020 may provide an accelerated graphics port (AGP) interface, a PCIe interface, or a communication streaming architecture (CSA) interface.

The graphics card 2050 may be connected to the IOH 2020 through AGP or PCIe. The graphics card 2050 may control a display device (not shown) to display an image. The graphics card 2050 may include an internal processor and an internal semiconductor memory device for processing image data. According to some embodiments, the IOH 2020 may include a graphics device therein together with or instead of the graphics card 2050 disposed outside the IOH 2020. The graphics device included in the IOH 2020 may be referred to as integrated graphics. Also, the IOH 2020, including a memory controller and a graphics device, may be referred to as a graphics and memory controller hub (GMCH).

The ICH 2030 may perform data buffering and interface arbitration such that various system interfaces efficiently operate. The ICH 2030 may be connected to the IOH 2020 through an internal bus. For example, the IOH 2020 and the ICH 2030 may be connected to each other via a direct media interface (DMI), a hub interface, an enterprise Southbridge interface (ESI), or PCIe.

The ICH 2030 may provide various interfaces with peripheral devices. For example, the ICH 2030 may provide a USB port, a serial advanced technology attachment (SATA), a general purpose I/O (GPIO), a low pin count (LPC) bus, a serial peripheral interface (SPI), PCI, or PCIe.

According to some embodiments, at least two of the processor 2010, the IOH 2020, and the ICH 2030 may be realized in one chipset.

While the inventive concept has been particularly shown and described with reference to exemplary embodiments thereof, it will be understood that various changes in form and details may be made therein without departing from the spirit and scope of the following claims.

What is claimed is:

1. A memory device comprising:
a command decoder configured to receive a command and to detect a transition to an idle period, which is a data idle period, based on the received command;
a mode register configured to store an information selection signal for selecting internal information of the memory device and outputting the selected internal information during the idle period; and
a data pad configured to transmit the selected internal information to an external device during the idle period.

2. The memory device of claim 1, wherein the selected internal information comprises information about at least one of a function, a characteristic, and a mode of the memory device that is set in the mode register.

3. The memory device of claim 1, wherein the command decoder is further configured to control the memory device to enter a power-down mode in response to a power-down command, and the selected internal information comprises status information indicating that the memory device is in the power-down mode.

4. The memory device of claim 1, wherein the command decoder is further configured to control a memory cell row of the memory device to perform a self-refresh operation in response to a self-refresh command, and the selected internal information comprises information indicating that the self-refresh operation is performed.

5. The memory device of claim 4, further comprising a refresh address generator configured to generate a refresh address corresponding to the memory cell row on which the self-refresh operation is performed.

6. The memory device of claim 1, further comprising a temperature detector configured to sense an internal temperature of the memory device,
wherein the selected internal information comprises information about internal temperature of the memory device.

7. The memory device of claim 1, wherein the selected internal information is provided to a memory controller configured to transmit the command.

8. The memory device of claim 7, wherein the selected internal information is serially transmitted to the memory controller via a data line that is connected to the data pad.

9. The memory device of claim 7, wherein the selected internal information is transmitted to the memory controller in parallel via data lines that are respectively connected to a plurality of data pads.

10. A method of operating a memory device, the method comprising:
storing in a mode register an information selection signal for selecting internal information of the memory device and outputting the selected internal information;
receiving a command;
detecting a transition to an idle period, which is a data idle period, based on the received command; and
transmitting the selected internal information to an external device during the idle period.

11. The method of claim 10, further comprising setting at least one of a function, a characteristic, and a mode of the memory device in the mode register,
wherein the selected internal information comprises information about the at least one of the function, the characteristic, and the mode of the memory device that is set in the mode register.

12. The method of claim 10, further comprising controlling the memory device to enter a power-down mode in response to a power-down command,
wherein the selected internal information comprises status information indicating that the memory device is in the power-down mode.

13. The method of claim 10, further comprising performing a self-refresh operation with respect to a memory cell row of the memory device in response to a self-refresh command,
wherein the selected internal information comprises information indicating that the self-refresh operation is performed.

14. The method of claim 10, further comprising detecting an internal temperature of the memory device,
wherein the selected internal information comprises information about internal temperature of the memory device.

15. The method of claim 10, wherein the selected internal information is serially transmitted via a data line connected to the memory device.

16. The method of claim 10, wherein the selected internal information is transmitted in parallel via a plurality of data lines connected to the memory device.

17. A system comprising:
a memory device configured to provide internal information; and
a memory controller configured to control the memory device,
wherein the memory device comprises:
a command decoder configured to receive a command, the command decoder comprising an idle period detector configured to detect a transition to an idle period, which is a data idle period, based on the received command;
a mode register configured to select the internal information of the memory device and to output the selected internal information during the idle period; and
a data pad configured to transmit the selected internal information to the memory controller during the idle period.

18. The system of claim 17, wherein the selected internal information comprises at least one from among information about at least one of a function, a characteristic, and a mode of the memory device that is set in the mode register, information of processing a self-refresh operation of the memory device, power-down mode information of the memory device, and internal temperature information of the memory device.

19. The system of claim 18, further comprising a power management integrated circuit (PMIC) configured to block operating power from being supplied to the memory controller and the memory device based on the power-down mode information of the memory device.

20. The system of claim 18, wherein the selected internal information is serially transmitted to the memory controller via a data line connected to the data pad or transmitted to the memory controller in parallel via data lines respectively connected to a plurality of data pads.
